(19) United States
(12) Patent Application Publication
(10) Pub. No.: US 2017/0084825 A1
(43) Pub. Date: Mar. 23, 2017

(54) MAGNETIC TUNNEL JUNCTION DEVICE AND SEMICONDUCTOR MEMORY DEVICE

(71) Applicant: FUJITSU LIMITED, Kawasaki-shi (JP)

(72) Inventor: Koji Tsunoda, Tsukuba (JP)

(73) Assignee: FUJITSU LIMITED, Kawasaki-shi (JP)

(21) Appl. No.: 15/265,970

(22) Filed: Sep. 15, 2016

(30) Foreign Application Priority Data
Sep. 18, 2015 (JP) 2015-184888

(51) Int. Cl. H01L 43/08; G11C 11/16; H01L 27/22

(52) U.S. Cl. CPC H01L 43/08; H01L 27/228; G11C 11/161; G11C 11/165

(57) ABSTRACT

A magnetic tunnel junction device includes a first magnetic tunnel junction including a first free layer and a first pinned layer, the first pinned layer having magnetization thereof aligned in a first direction, and a second magnetic tunnel junction including a second free layer and a second pinned layer, the second free layer being magnetically coupled to the first free layer via a spacer, and the second pinned layer having magnetization thereof aligned in a second direction opposite the first direction, wherein a magnetization direction of the first free layer is configured to be retained in a nonvolatile manner upon being selectively set to either the first direction or the second direction, and a readiness of the magnetization of the second free layer to be reversed varies depending on the magnetization direction of the first free layer.

### CROSS-REFERENCE TO RELATED APPLICATIONS

The present application is based upon and claims the benefit of priority from the prior Japanese Patent Application No. 2015-184888 filed on Sep. 18, 2015, with the Japanese Patent Office, the entire contents of which are incorporated herein by reference.

### FIELD

The disclosures herein relate to a magnetic tunnel junction device and a semiconductor memory device.

### BACKGROUND

A magnetoresistive random access memory (MRAM) has a memory cell in which ferromagnetic metal electrodes are disposed on the upper and lower surfaces of a tunnel insulating film. The tunnel resistance of magnetic tunnel junction (MTJ) varies in response to the relative magnetization directions of these ferromagnetic metal electrodes, thereby storing data. One of the two ferromagnetic metal electrodes is a pinned layer having a fixed magnetization direction, and the other is a free layer having a changeable magnetization direction. MTJ exhibits a low resistance value when the magnetization direction of the pinned layer and the magnetization direction of the free layer are parallel to each other (i.e., in the parallel state), and exhibits a high resistance value when they are antiparallel to each other (i.e., in the antiparallel state).

The magnetization direction of the free layer may be changed (i.e., reversed) by use of a magnetic field induced by an electric current flowing through a wire. In this case, the amount of a write current required for magnetization reversal is reciprocal to the cubic volume of the free layer, which hampers the effort to miniaturize memory cells. As is known in the art, the magnetization of free layer may alternatively be reversed by spin-transfer torque. In the case of spin-transfer torque, the amount of electric current required for overwrite is proportional to the cubic volume of the MTJ free layer, which means that the amount of current required for overwrite decreases as cells are further miniaturized. The use of spin injection for magnetization reversal increases the possibility of practical implementation of an MRAM as a nonvolatile memory device suitable for miniaturization.

The MRAM has the problem of a low magnetoresistance ratio (i.e., MR ratio), which is defined as a ratio of MTJ's magnetoresistance between the low-resistance state “0” and the high-resistance state “1”. As a technology for solving this problem, the CoFeB/MgO/CoFeB structure utilizing MgO as a tunnel insulating film and CoFeB as ferromagnetic metal electrodes is known to have a relatively high MR ratio (see Patent Documents 1 and 2, for example). As is also known in the art, the utilization of interface perpendicular magnetic anisotropy induced at the interface between MgO and CoFeB allows CoFeB/MgO/CoFeB, which typically serves as an in-plane magnetization MTJ, to be used as a perpendicular magnetization MTJ (see Non-Patent Document 1, for example). Compared with the in-plane magnetization MTJ, the perpendicular magnetization MTJ has a higher efficiency in magnetization reversal induced by spin injection, and is thus expected to enable a smaller electric current to perform an overwrite operation while providing a compatible thermal stability when used in an MRAM. Research and development efforts have been actively underway with regard to MRAMs based on magnetization reversal by spin injection (i.e., STT-MRAMs) which utilize an interface perpendicular MTJ having the CoFeB/MgO/CoFeB structure (see Non-Patent Document 2, for example).

As previously described, the STT-MRAM enables the miniaturization of an MTJ from the viewpoint of the amount of overwrite electric current. However, miniaturizing an MTJ serves to increase the relative variation of device area size (as defined by a normalized value obtained by dividing the variation of device area size by the average of device area size), resulting in an increase in the relative variation of device resistance (as defined by a normalized value obtained by dividing the variation of device resistance by the average of device resistance). In the case of an interface perpendicular MTJ utilizing interface perpendicular magnetic anisotropy at the interface between MgO and CoFeB, there is a need to set the film thickness of CoFeB below a certain thickness, so that a resistance change ranges from a factor of approximately 2 (i.e., a magnetoresistance ratio of 100%) to a factor of approximately 3 (i.e., a magnetoresistance ratio of 200%) at the maximum.

The factor of 2 or 3 as described above is significantly lower than the resistance changes of other nonvolatile memory devices. When the relative variation of resistance increases due to the miniaturization of MTJ, a large-scale memory array may end up having a resistance distribution of memory cells having the value “0” overlapping a resistance distribution of memory cells having the value “1”. This results in the problem of erroneous data reading.

In order to overcome the problem noted above, study has been made on a self-reference circuit that utilizes the MTJ subjected to data reading also as a reference cell (see Non-Patent Document 3, for example). As an example, the operation sequence of a typical self-reference circuit includes steps as follows:
1) voltage V1 observed by causing read current I1 to flow through an MTJ is stored in a capacitor C1;
2) “0” is written to the MTJ (i.e., placing the MTJ in the low-resistance state).
3) voltage V2 observed by causing read current I2 (I2>I1) to flow through the MTJ is stored in a capacitor C2;
4) based on comparison of voltage V1 of C1 with voltage V2 of C2, data “1” is detected in the case of V1>V2, and data “0” is detected in the case of V1<V2; and
5) “1” is written back to the MTJ when the detection result is “1”.

The use of the self-reference circuit described above obviates the need for a reference cell, and allows the cell state to be correctly read even when the variance of device resistance is large. On the other hand, reading one information bit in the self-reference circuit involves two read operations and at least one write operation, possibly two write operations at the maximum. Such operations result in a lengthy read time and relatively large power consumption.

In order to overcome the problems described above, study has been made on a nondestructive self-reference circuit that requires no write operation at the time of read operation (see Non-Patent Document 4, for example). This circuit utilizes the fact that the voltage dependency of an MTJ resistance value is responsive to the resistance state (i.e., the data state). In general, the voltage dependency of MTJ resistance in the low-resistance state is lower, and the voltage dependency of MTJ resistance in the high-resistance state is higher. Accordingly, properly adjusting a ratio between read currents I1 and I2 and the division ratio of the potential divider circuit in the following operation sequence enables only two read operations to detect the device state:
1) voltage V1 observed by causing read current I1 to flow through an MTJ is stored in a capacitor C1;
2) voltage V2 is obtained by dividing a voltage observed by causing I2 (>11) to flow through the MTJ; and
3) based on comparison of V1 with V2, data “1” is detected in the case of V1>V2, and data “0” is detected in the case of V1<V2.

The nondestructive self-reference circuit described above does not need a write operation at the time of read operation, which enables a read operation that is performed faster with lower power consumption than in the case of a usual self-reference circuit. However, the read operation is performed by utilizing the fact that the voltage dependency of resistance differs between the “0”-data state and the “1”-data state, which means that the operation margin is relatively small. Unless the ratio between read currents and the division ratio of a potential divider circuit are accurately controlled, a proper data read operation may not be realized.
[Patent Document 1] International Publication Pamphlet No. WO 2005088745
[Patent Document 2] Japanese Laid-open Patent Publication No. 2006-80116
[Patent Document 3] International Publication Pamphlet No. WO 2010137679
[Non-Patent Document 1] S. Ikeda, et al., “A perpendicular-anisotropy CoFeB—MgO magnetic tunnel junction,” Nature Materials, Vol. 9, September 2010, pp 721-724
[Non-Patent Document 2] D. C. Worledge, et al., “Spin torque switching of perpendicular Ta|CoFeB|MgO-based magnetic tunnel junctions,” Applied Physics Letters 98 022501 (2011)
[Non-Patent Document 3] Gitae Jeong, et al., “A 0.24 μ m 2.0V 1T1MTJ 16 kb NV Magnetoresistance RAM with Self Reference Sensing,” 2003 IEEE International Solid-State Circuits Conference, Session 16, Paper 16.2
[Non-Patent Document 4] Y Chen, et al., “A Nondestructive Self-Reference Scheme for Spin-Transfer Torque Random Access Memory (STT-RAM),” DATE '10 Proceedings of the Conference on Design, Automation and Test in Europe, pp 148-153

### SUMMARY

According to an aspect of the embodiment, a magnetic tunnel junction device includes a first magnetic tunnel junction including a first free layer and a first pinned layer, the first pinned layer having magnetization thereof aligned in a first direction, and a second magnetic tunnel junction including a second free layer and a second pinned layer, the second free layer being magnetically coupled to the first free layer via a spacer, and the second pinned layer having magnetization thereof aligned in a second direction opposite the first direction, wherein a magnetization direction of the first free layer is configured to be retained in a nonvolatile manner upon being selectively set to either the first direction or the second direction, and a readiness of the magnetization of the second free layer to be reversed varies depending on the magnetization direction of the first free layer.

According to an aspect of the embodiment, a semiconductor memory device includes a magnetic tunnel junction device and a circuit configured to compare values of an electric variable responsive to resistance values of the magnetic tunnel junction device between two different conditions regarding a voltage across the magnetic tunnel junction device, and configured to output a detection value of data stored in the magnetic tunnel junction device in response to a result of comparison of the values of the electric variable, wherein the magnetic tunnel junction device includes a first magnetic tunnel junction including a first free layer and a first pinned layer, the first pinned layer having magnetization thereof aligned in a first direction, and a second magnetic tunnel junction including a second free layer and a second pinned layer, the second free layer being magnetically coupled to the first free layer via a spacer, and the second pinned layer having magnetization thereof aligned in a second direction opposite the first direction, wherein a magnetization direction of the first free layer is configured to be retained in a nonvolatile manner upon being selectively set to either the first direction or the second direction, and a readiness of the magnetization of the second free layer to be reversed varies depending on the magnetization direction of the first free layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating the basic configuration and operation of a magnetic tunnel junction;

FIG. 2 is a drawing illustrating an example of the configuration of a magnetic tunnel junction device according to an embodiment;

FIG. 3 is a drawing illustrating an example of the operation of the MTJ device illustrated in FIG. 2;

FIG. 4 is a drawing illustrating an example of the voltage-to-resistance characteristics of the MTJ device;

FIGS. 5A through 5C are drawings illustrating the voltage-to-resistance characteristics of a first MTJ and the voltage-to-resistance characteristics of a second MTJ separately from each other;

FIG. 6 is a drawing illustrating examples of the voltage-to-resistance characteristics and read voltages of a prototype MTJ device;

FIG. 7 is a drawing illustrating examples of a difference in the resistance value at the time of a read operation of an MTJ device;

FIG. 8 is a drawing illustrating an example of the configuration of a read circuit for an MTJ device;

FIG. 9 is a drawing illustrating an example of the configuration of a semiconductor memory device;

FIG. 10 is a drawing illustrating the configuration of a prototype MTJ device;

FIG. 11 is a drawing illustrating the magnetic-field-to-resistance characteristics of the prototype MTJ device;

FIG. 12 is a drawing illustrating an example of a process step of making the MTJ device;

FIG. 13 is a drawing illustrating an example of a process step of making the MTJ device;

FIG. 14 is a drawing illustrating an example of a process step of making the MTJ device;

FIG. 15 is a drawing illustrating an example of a process step of making the MTJ device;

FIG. 16 is a drawing illustrating an example of a process step of making the MTJ device;

FIG. 17 is a drawing illustrating an example of a process step of making the MTJ device;

FIG. 18 is a drawing illustrating an example of a process step of making the MTJ device;

FIG. 19 is a drawing illustrating an example of a process step of making the MTJ device;

FIG. 20 is a drawing illustrating an example of the configuration of a pinned layer;

FIG. 21 is a drawing illustrating an example of the configuration of a free layer; and

FIG. 22 is a drawing illustrating an example of the configuration of a free layer.

### DESCRIPTION OF EMBODIMENTS

In the following, embodiments of the invention will be described with reference to the accompanying drawings. In these drawings, the same or corresponding elements are referred to by the same or corresponding numerals, and a description thereof will be omitted as appropriate.

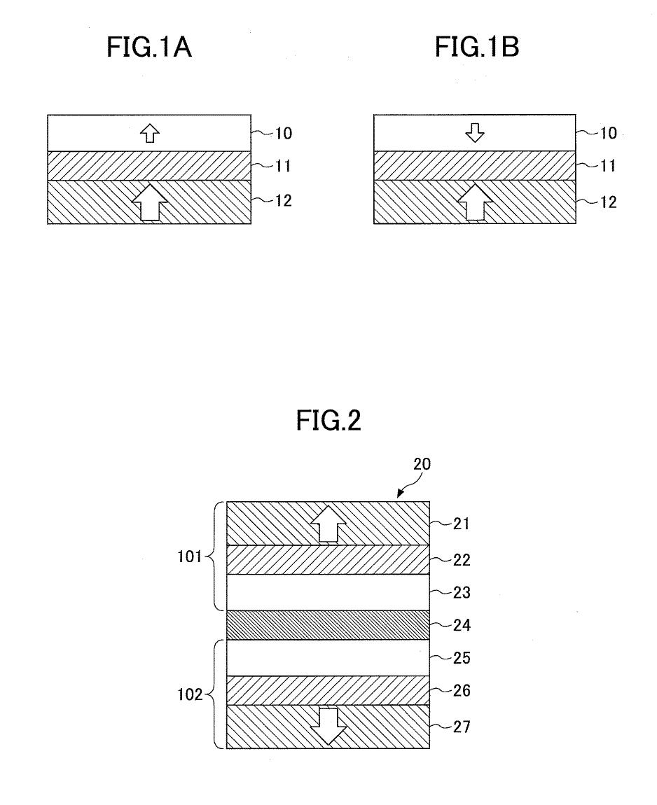

FIGS. 1A and 1B are drawings illustrating the basic configuration and operation of a magnetic tunnel junction. The magnetic tunnel junction (MTJ) illustrated in FIGS. 1A and 1B include a free layer 10, a tunnel insulating film 11, and a pinned layer 12. The MTJ illustrated in FIGS. 1A and 1B is a perpendicular magnetization MTJ, which has a magnetization direction aligned in a direction perpendicular to the surface of each layer (i.e., in a thickness direction of each layer), rather than in a direction parallel to the surface of each layer.

In the state illustrated in FIG. 1A, the magnetization direction of the free layer 10 is upwards as illustrated by the arrow in the layer, and the magnetization direction of the pinned layer is upwards as illustrated by the arrow in the layer. When the magnetization direction of the free layer 10 and the magnetization direction of the pinned layer 12 are in the parallel state (i.e., point in the same direction), the MTJ is placed in the low-resistance state to exhibit a low-resistance value. In the state illustrated in FIG. 1B, the magnetization direction of the free layer 10 is downwards as illustrated by the arrow in the layer, and the magnetization direction of the pinned layer is upwards as illustrated by the arrow in the layer. When the magnetization direction of the free layer 10 and the magnetization direction of the pinned layer 12 are in the antiparallel state (i.e., point in the opposite directions), the MTJ is placed in the high-resistance state to exhibit a high-resistance value. Setting the MTJ either in the low-resistance state or in the high-resistance state allows information to be stored in the MTJ.

As previously described, magnetization reversal induced by spin injection by use of spin-transfer torque (i.e., a torque of a spin-polarized electron) enables the magnetization reversal of the free layer 10. In the magnetization state illustrated in FIG. 1B, for example, voltage is applied such that the free layer 10 is coupled to the positive polarity, and the pinned layer 12 is coupled to the negative polarity. The application of such a voltage causes electrons to run from the pinned layer 12 to the free layer 10 (i.e., run upwards in FIG. 1B). While the possibility of electrons passing through the pinned layer 12 is low when the electrons have a spin in the direction opposite the magnetization direction of the pinned layer 12, the electrons having a spin in the same direction as the magnetization direction of the pinned layer 12 pass through the pinned layer 12 with high probability to reach the free layer 10. Due to the effect of the electrons having a spin in the same direction as the magnetization direction of the pinned layer 12, the magnetization direction of the free layer 10 is reversed, so that the free layer 10 is placed in the state (as illustrated in FIG. 1A) in which the free layer 10 has the magnetization direction in the same direction as the magnetization direction of the pinned layer 12.

Further, in the magnetization state illustrated in FIG. 1A, voltage is applied such that the pinned layer 12 is coupled to the positive polarity, and the free layer 10 is coupled to the negative polarity. The application of such a voltage causes electrons to run from the free layer 10 to the pinned layer 12 (i.e., run downwards in FIG. 1A). While electrons having a spin in the same direction as the magnetization direction of the pinned layer pass through the pinned layer 12 with high probability, electrons having a spin in the direction opposite the magnetization direction of the pinned layer 12 are partially bounced by the pinned layer 12 to affect the free layer 10. Due to the effect of the electrons having a spin in the direction opposite the magnetization direction of the pinned layer 12, the magnetization direction of the free layer 10 is reversed, so that the free layer 10 is placed in the state (as illustrated in FIG. 1B) in which the free layer 10 has the magnetization direction in the direction opposite the magnetization direction of the pinned layer 12.

FIG. 2 is a drawing illustrating an example of the configuration of a magnetic tunnel junction device according to an embodiment. A magnetic tunnel junction device (MTJ device) 20 illustrated in FIG. 2 includes a first MTJ 101 and a second MTJ 102. The first MTJ 101 includes a first free layer 23 and a first pinned layer 21 that has a magnetization direction aligned to the first direction (which is the upward direction in the example illustrated in FIG. 2). The first MTJ 101 has a tunnel insulating film 22 disposed between the first pinned layer 21 and the first free layer 23.

The second MTJ 102 includes a second free layer 25 coupled to the first free layer 23 via a spacer 24, and includes a second pinned layer 27 having a magnetization direction aligned in the second direction (which is the downward direction in the example illustrated in FIG. 2) that is opposite the first direction. The second MTJ 102 has a tunnel insulating film 26 disposed between the second free layer 25 and the second pinned layer 27. The magnetization direction of the second pinned layer as shown by the arrow illustrated inside the second pinned layer 27 is opposite the magnetization direction of the first pinned layer 21 shown by the arrow illustrated in the first pinned layer 21. It suffices for the magnetization directions to be opposite from each other, so that the magnetization direction of the first pinned layer 21 may be downward in FIG. 2 while the magnetization direction of the second pinned layer 27 is upward in FIG. 2.

The first MTJ 101 is a device capable of nonvolatile information retention similar to the MTJ described in connection with FIGS. 1A and 1B. Namely, the magnetization of the first free layer 23 of the first MTJ 101 is capable of being selectively set, and thereafter retained in a nonvolatile manner, in either the first direction (i.e., the upward direction in FIG. 2) or the second direction (i.e., the downward direction in FIG. 2). Specifically, the magnetization direction of the first free layer 23 is stably maintained to be either the first direction or the second direction without a voltage or magnetic field being applied to the MTJ device 20 from an external source.

The first free layer 23 of the first MTJ 101 and the second free layer 25 of the second MTJ 102 are magnetically coupled to each other through the spacer 24, and are situated next to each other across the spacer 24. Accordingly, the stray magnetic field from the first free layer 23 having an effect on the second free layer 25 has a direction varying in response to the magnetization direction of the first free layer 23. As a result, the size of the stray magnetic field generated by an entirety of the first pinned layer 21, the first free layer 23, and the second pinned layer 27 and having an effect on the second free layer 25 differs depending on the magnetization direction of the first free layer 23.

With the above-noted arrangement, the readiness of the magnetization of the second free layer 25 of the second MTJ 102 to be reversed varies depending on the magnetization direction of the first free layer 23. Specifically, the size of a voltage or magnetic field that is applied to the MTJ device 20 to reverse the magnetization of the second free layer 25 varies depending on the magnetization direction of the first free layer 23. The magnetic coercive force of the second free layer 25 may be significantly lower than the magnetic coercive force of the first free layer 23. Specifically, the magnetization direction of the second free layer 25 may always be aligned in the second direction due to the stray magnetic field from the second pinned layer 27 regardless of the magnetization direction of the first free layer 23 when an applied voltage or magnetic field is zero.

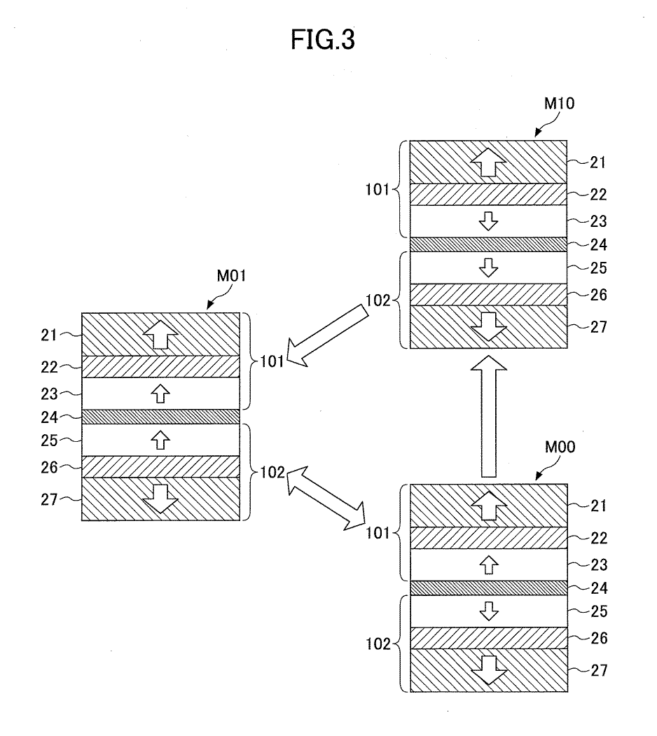

FIG. 3 is a drawing illustrating an example of the operation of the MTJ device 20 illustrated in FIG. 2. As illustrated in FIG. 3, the MTJ device 20 assumes one of the three states, i.e., a state M00, a state M10, and a state M01. The first numeral “0” or “1” immediately following the character “M” indicates the resistance state of the first MTJ 101, and the second numeral “0” or “1” indicates the resistance state of the second MTJ 102. “0” indicates the low-resistance state, and “1” indicates the high-resistance state.

In the state M00 and the state M01, the first free layer 23 of the first MTJ 101 is magnetized in the first direction, i.e., in the same direction as the magnetization direction of the first pinned layer 21. Namely, the first MTJ 101 is set in the low-resistance state. In the state M10, the first free layer 23 of the first MTJ 101 is magnetized in the second direction, i.e., in the direction opposite the magnetization direction of the first pinned layer 21. Namely, the first MTJ 101 is set in the high-resistance state.

In the state M00 and the state M10, the second free layer 25 of the second MTJ 102 is magnetized in the second direction, i.e., in the same direction as the magnetization direction of the second pinned layer 27. Namely, the second MTJ 102 is set in the low-resistance state. In the state M01, the second free layer 25 of the second MTJ 102 is magnetized in the first direction, i.e., in the direction opposite the magnetization direction of the second pinned layer 27. Namely, the second MTJ 102 is set in the high-resistance state.

In the absence of a voltage or magnetic field applied to the MTJ device 20 from an external source, as previously described, the magnetization direction of the second free layer 25 of the second MTJ 102 may always be aligned in the second direction, which is the same direction as the magnetization direction of the second pinned layer 27. In the following description, the MTJ device 20 is placed in the state M00 in the initial state when neither voltage nor a magnetic field is applied. The first MTJ 101 in the state M00 is in the low-resistance state. In the following, a description will be given of a case in which voltage is applied to cause a state transition. It should be noted, however, that application of a magnetic field from an external source will also create the same or similar state transition.

In the state M00, voltage is applied such that the first pinned layer 21 is coupled to the positive polarity, and the second pinned layer 27 is coupled to the negative polarity. Application of a sufficiently high voltage causes the magnetization direction of the first free layer 23 to be reversed into the second direction through magnetization reversal induced by spin injection as described in connection with FIGS. 1A and 1B. With this, the MTJ device 20 makes a transition to the state M10. Namely, the first MTJ 101 is set to the high-resistance state.

After the transition to the state M10, this state M10 is maintained when neither voltage nor magnetic field is applied from an external source. This is because the first free layer 23 of the first MTJ 101 has a sufficient magnetic coercive force, and is thus capable of maintaining the current magnetization direction in a nonvolatile and stable manner. This is also because the second free layer 25 of the second MTJ 102 has a small magnetic coercive force so that the magnetization of the second free layer 25 always align itself in the same direction as the magnetization direction of the second pinned layer 27 when neither voltage nor a magnetic field is applied.

In the state M10, voltage is applied such that the first pinned layer 21 is coupled to the negative polarity, and the second pinned layer 27 is coupled to the positive polarity. Application of a sufficiently high voltage causes the magnetization direction of the first free layer 23 to be reversed into the first direction through magnetization reversal induced by spin injection as described in connection with FIGS. 1A and 1B. Further, the magnetization direction of the second free layer 25 of the second MTJ 102 may be reversed simultaneously with the reversal of the magnetization direction of the first free layer 23 in the first MTJ 101. Such a simultaneous reversal occurs because the torques of electron spins responsive to the applied voltage lie in such a direction to reverse the magnetization direction of the second free layer 25, and also because the stray magnetic field from the first free layer 23 functions in such a manner as to cause the second free layer 25 to align in the same direction. As a result, the MTJ device 20 makes a transition to the state M01. Namely, the first MTJ 101 is set to the low-resistance state.

After the transition to the state M01, a change to the state in which neither voltage nor magnetic field is applied from an external source causes the MTJ device 20 to make a transition from the state M01 to the state M00. This is because the first free layer 23 of the first MTJ 101 has a sufficient magnetic coercive force, and is thus capable of maintaining the current magnetization direction in a nonvolatile and stable manner. This is also because the second free layer 25 of the second MTJ 102 has a small magnetic coercive force so that the magnetization of the second free layer 25 always align itself in the same direction as the magnetization direction of the second pinned layer 27 when neither voltage nor a magnetic field is applied.

In the manner described above, the first MTJ 101 of the MTJ device 20 can be set to the high-resistance state or to the low-resistance state, and the resistance state in which the first MTJ 101 is placed can be maintained when neither voltage nor a magnetic field is applied from an external source. Data written in the MTJ device 20 is read by utilizing the fact that the readiness of the magnetization of the second free layer 25 to be reversed varies depending on the magnetization direction of the first free layer 23. This point will be described in the following.

The MTJ device 20 can make a transition in both directions between the state M00 and the state M01 as illustrated in FIG. 3 by the arrow indicating both directions between the state M00 and the state M01. On the other hand, a transition to the state M10 can only be made from the state M00, and a transition from the state M10 can only be made to the state M01. As was previously described, the MTJ device 20 is in the state M10 or in the state M00 when neither voltage nor a magnetic field is applied from an external source. In order to cause the MTJ device 20 to make a transition from the state M10 to the state M01 or from the state M00 to the state M01, voltage is applied such that the first pinned layer is coupled to the negative polarity and the second pinned layer 27 is coupled to the positive polarity.

Making a transition from the state M10 to the state M01 involves reversing the magnetization direction of the first free layer 23, which has a relatively strong magnetic coercive force and is thus capable of maintaining its state of magnetization in a nonvolatile manner. Because of this, application of a relatively high voltage enables the transition to the state M01. In the state M10, further, the magnetization direction of the second free layer 25 is the same as the magnetization direction of the first free layer 23 situated next thereto, so that the magnetization of the second free layer 25 is relatively stable. As a result, reversing the second free layer 25 involves application of a relatively high voltage.

On the other hand, making a transition from the state M00 to the state M01 only involves reversing the magnetization direction of the second free layer 25, which has a relatively week magnetic coercive force and is thus incapable of maintaining its state of magnetization in a nonvolatile manner. Because of this, application of a relatively low voltage enables the transition to the state M01. Further, in the state M00, the magnetization direction of the second free layer 25 is opposite to the magnetization direction of the first free layer 23 situated next thereto, so that the magnetization of the second free layer 25 is relatively unstable. Application of a relatively low voltage thus enables the transition to the state M01.

In summary, V1<V2 is satisfied when a voltage required to make a transition from the state M00 to the state M01 is denoted as V1, and a voltage required to make a transition from the state M10 to the state M01 is denoted as V2. In the following, a description will be given of applied voltages vr1 and vr2 where vr1<V1<vr2<V2. Application of either vr1 or vr2 to the MTJ device 20 in the state M10 will not serve to change the state, and the state M10 will be maintained. Namely, the high-resistance state of the first MTJ 101 and the low-resistance state of the second MTJ 102 are maintained as they are. In this case, the resistance value of the MTJ device 20 as a whole under the condition of the applied voltage vr1 and the resistance value of the MTJ device 20 as a whole under the condition of the applied voltage vr2 are resistance values of the same resistance state. In reality, however, the resistance value of each MTJ exhibits voltage dependency, and shows a tendency to decrease as the applied voltage increases. A resistance value r2 under the condition of the applied voltage vr2 is thus lower than a resistance value r1 under the condition of the applied voltage vr1. Namely, r1>r2 is satisfied.

In the case of the MTJ device 20 in the state M00, on the other hand, the state M00 is maintained when the voltage vr1 is applied, but a transition to the state M10 occurs when the voltage vr2 is applied. Namely, while the low-resistance state of the first MTJ 101 and the low-resistance state of the second MTJ 102 are both maintained under the condition of the applied voltage vr1, the application of the voltage vr2 causes the second MTJ 102 to make a transition to the high-resistance state while the first MTJ 101 still remains in the low-resistance state. Accordingly, the resistance value of the MTJ device 20 as a whole under the condition of the applied voltage vr1 and the resistance value of the MTJ device 20 as a whole under the condition of the applied voltage vr2 are resistance values of different resistance states between which the state of the second MTJ 102 differs. An increase in the resistance value of the second MTJ 102 caused by a change in the resistance state may be greater than a decrease in the resistance value attributable to the voltage dependency of each MTJ. In such a case, the resistance value r2 of the entire device under the condition of the applied voltage vr2 is greater than the resistance value r1 of the entire device under the condition of the applied voltage vr1. Namely, r1<r2 is satisfied. In reality, the voltage dependency of the resistance value of MTJ in the low-resistance state is relatively small, so that the condition of r1<r2 is easily satisfied.

In the manner described above, comparing the resistance value r1 of the entire device under the condition of the applied voltage vr1 with the resistance value r2 of the entire device under the condition of the applied voltage vr2 allows a determination to be made as to whether the MTJ device 20 is in the state M10 or in the state M00. Namely, a determination is made as to whether the first MTJ 101 is in the high-resistance state or in the low-resistance state. Specifically, the state M10 is detected in the case of r1>r2, and the state M00 is detected in the case of r1<r2.

In this manner, which one of the resistance values r1 and r2 compared with each other is greater than the other is reversed between the two different states (i.e., M10 and M00), thereby enabling an accurate data detection that ensures a sufficient margin. When a data detection is made by utilizing the voltage dependency of the resistance value of a single MTJ as in the related art, the resistance value decreases as the applied voltage increases regardless of whether the MTJ is in the high-resistance state or in the low-resistance state. Namely, which one of the resistance values compared with each other is greater than the other is not reversed in the related art. In the case of the MTJ device 20, on the other hand, the first MTJ 101 serves as an MTJ for information storage, and the second MTJ 102 serves as a read-purpose MTJ that exhibits varying voltage-to-resistance characteristics in response to the information stored in the first MTJ 101. The provision of such a data-read-purpose second MTJ 102 enables an accurate data detection that provides a sufficient margin.

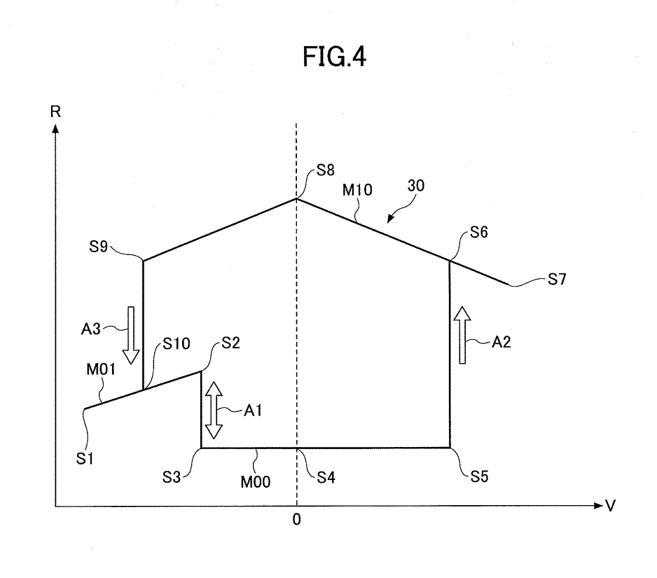

FIG. 4 is a drawing illustrating an example of the voltage-to-resistance characteristics of the MTJ device 20. The horizontal axis represents the voltage applied to the MTJ device 20, and the vertical axis represents the resistance value of the entire MTJ device 20. In the region in which the applied voltage is negative, the first pinned layer 21 is on the negative-polarity side, and the second pinned layer 27 is on the positive-polarity side. In the region in which the applied voltage is positive, the first pinned layer 21 is on the positive-polarity side, and the second pinned layer 27 is on the negative-polarity side. The resistance value that the entire MTJ device 20 exhibits for each voltage value is illustrated by hysteresis characteristics 30.

In a voltage-&-resistance condition S1 (which will hereinafter be referred to simply as a “condition”), a sufficiently high negative voltage is applied, so that the MTJ device 20 is set in the state M01. As the magnitude of the negative applied voltage diminishes, the resistance value slightly increases in accordance with the voltage dependency of the resistance value, and reaches a condition S2. Diminishing the applied voltage below the condition S2 causes a state transition to occur as illustrated by an arrow A1, so that the MTJ device 20 makes a transition from the state M01 to the state M00. Through this state transition, the second MTJ 102 changes from the high-resistance state to the low-resistance state. The resistance value of the entire device thus exhibits a significant drop as illustrated by a difference in the vertical position between the condition S2 and a condition S3 in FIG. 4.

The applied voltage is thereafter changed from the condition S3 to zero as indicated by a condition S4. In this condition S4 where the applied voltage is zero, the state M00 is maintained, and the resistance value of the entire device stays at a low level. A positive voltage is thereafter applied, and the applied positive voltage is increased to reach a condition S4. Increasing the applied voltage above the condition S5 causes a state transition to occur as illustrated by an arrow A2, so that the MTJ device 20 makes a transition from the state M00 to the state M10. Through this state transition, the first MTJ 101 changes from the low-resistance state to the high-resistance state. The resistance value of the entire device thus exhibits a significant increase as illustrated by a difference in the vertical position between the condition S5 and a condition S6 in FIG. 4. It may be noted that a change (i.e., the difference in the vertical position between S5 and S6) in the resistance value of the first MTJ 101 caused by a reversal in the magnetization direction of the first free layer 23 may be smaller than a change (i.e., the difference in the vertical position between S2 and S3) in the resistance value of the second MTJ 102 caused by a reversal in the magnetization direction of the second free layer 25. The second MTJ 102 is important for the purpose of data reading. The above-noted conditions ensure reliable data reading.

The positive applied voltage is further increased from the condition S6 to reach a condition S7 by which the first MTJ 101 of the MTJ device 20 is placed in a sufficiently strong antiparallel state. Subsequently, the magnitude of the positive applied voltage is diminished from a condition S7 to become zero as indicated by a condition S8. In this condition S8 where the applied voltage is zero, the state M10 set in the condition S6 is maintained, so that the resistance value of the entire device also stays at a relatively high level.

A negative voltage is thereafter applied, and the applied negative voltage is increased to reach a condition S9. Increasing the magnitude of the applied voltage above the condition S9 causes a state transition to occur as illustrated by an arrow A3, so that the MTJ device 20 makes a transition from the state M10 to the state M01. Through this state transition, the first MTJ 101 moves from the high-resistance state to the low-resistance state to bring about a large decrease in the resistance value, and the second MTJ 102 moves from the low-resistance state to the high-resistance state to bring about a small increase in the resistance value. As a result, the resistance value of the entire device decreases as illustrated by a difference in the vertical position between the condition S9 and a condition S10 in FIG. 4.

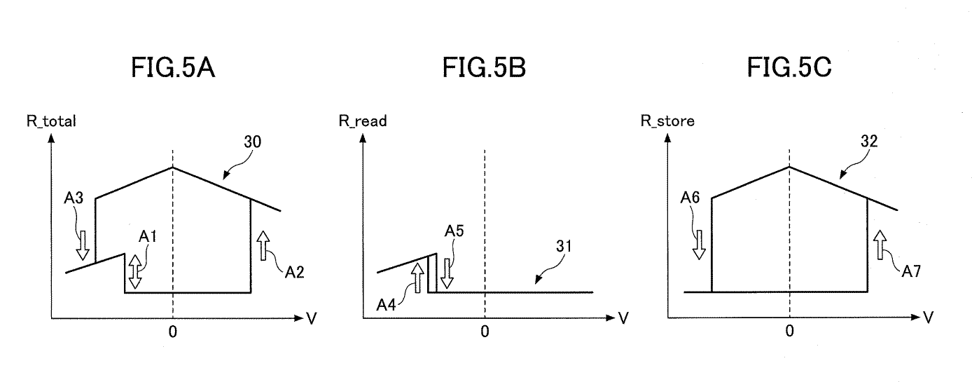

FIGS. 5A through 5C are drawings illustrating the voltage-to-resistance characteristics of the first MTJ 101 and the voltage-to-resistance characteristics of the second MTJ 102 separately from each other. In FIGS. 5A through 5C, the horizontal axis represents the voltage applied to each MTJ, and the vertical axis represents the resistance value of each MTJ. FIG. 5A is a drawing similar to FIG. 4, and illustrates the voltage applied to the MTJ device 20 and the resistance value of the entire MTJ device 20. FIG. 5B illustrates the voltage applied to the second MTJ 102 and the resistance value of the second MTJ 102.

FIG. 5C illustrates the voltage applied to the first MTJ 101 and the resistance value of the first MTJ 101. It may be noted that the directions of the voltage used in FIG. 5 are the same as the directions of the voltage applied to the MTJ device 20 in FIG. 4. Namely, in the case of the second MTJ 102 illustrated in FIG. 5B, the positive applied voltage direction corresponds to the arrangement in which the second free layer 25 is on the positive-polarity side and the second pinned layer 27 is on the negative-polarity side. Further, in the case of the first MTJ 101 illustrated in FIG. 5C, the positive applied voltage direction corresponds to the arrangement in which the first free layer 23 is on the negative-polarity side and the first pinned layer 21 is on the positive-polarity side.

In the case of the first MTJ 101 illustrated in FIG. 5C, an increase in the positive applied voltage causes a state transition to occur as illustrated by an arrow A7 in hysteresis characteristics 32, so that a transition occurs from the low-resistance state to the high-resistance state. As a negative applied voltage is subsequently increased, a state transition occurs as illustrated by an arrow A6, so that a transition occurs from the high-resistance state to the low-resistance state. Since the loop of the hysteresis characteristics 32 overlaps the position at which the applied voltage is zero, there are two different stable states at the point where the applied voltage is zero. These two stable states serve to store information that is either “0” or “1”.

In the case of the second MTJ 102 illustrated in FIG. 5B, an increase in the negative applied voltage causes a state transition to occur as illustrated by an arrow A4 in hysteresis characteristics 31, so that a transition occurs from the low-resistance state to the high-resistance state. As a negative applied voltage is subsequently decreased, a state transition occurs as illustrated by an arrow A5, so that a transition occurs from the high-resistance state to the low-resistance state. Since the loop of the hysteresis characteristics 31 is situated further to the left (i.e., toward the negative voltage side) than the point at which the applied voltage is zero, there is only one stable state at the point where the applied voltage is zero. It may be noted that, strictly speaking, the position of the transition illustrated by the arrow A4 in the hysteresis characteristics 31 varies depending on the resistance state (i.e., memory state) of the first MTJ 101 illustrated in FIG. 5C when taking into account the effect on the second MTJ 102 of a stray magnetic field from the first MTJ 101.

FIG. 5A illustrates the voltage-to-resistance characteristics of the MTJ device 20. The sum of the voltage-to-resistance characteristics of the second MTJ 102 illustrated in FIG. 5B and the voltage-to-resistance characteristics of the first MTJ 101 illustrated in FIG. 5C is equal to the voltage-to-resistance characteristics of the MTJ device 20. Namely, the sum of the hysteresis characteristics 31 of the second MTJ 102 illustrated in FIG. 5B and the hysteresis characteristics 32 of the first MTJ 101 illustrated in FIG. 5C is equal to the hysteresis characteristics 30 illustrated in FIG. 5A. The transition indicated by the arrow A1 in the hysteresis characteristics 30 illustrated in FIG. 5A corresponds to the transitions indicated by the arrows A4 and A5 in FIG. 5B. Further, the transition indicated by the arrow A3 in the hysteresis characteristics 30 illustrated in FIG. 5A corresponds to the transition indicated by the arrow A6 in FIG. 5C and the transition indicated by the arrow A4 in FIG. 5B. Moreover, the transition indicated by the arrow A2 in the hysteresis characteristics 30 illustrated in FIG. 5A corresponds to the transition indicated by the arrow A7 in FIG. 5C. In reality, the transition indicated by the arrow A1 in the hysteresis characteristics 30 illustrated in FIG. 5A also has a hysteresis characteristic loop similarly to the transitions indicated by the arrows A4 and A5 in FIG. 5B. For the sake of simplicity of illustration, however, this transition is depicted simply as a step change in the voltage-to-resistance characteristics.

As can be understood from the explanations provided in connection with FIGS. 5A through 5C, the two stable states corresponding to the state M10 and the state M00 existing when the applied voltage from an external source is zero, as indicated by the conditions S8 and S4 in FIG. 4, respectively, are brought about by the hysteresis characteristic loop of the first MTJ 101. Further, the state transition between the state M00 and the state M01 (i.e., the state transition indicated by the arrow A1), as indicated by the conditions S2 and S3, respectively, are brought about the loop of the hysteresis characteristics of the second MTJ 102. If the loop of the hysteresis characteristics of the second MTJ 102 is situated further to the right than in the case illustrated in FIG. 4 (see FIG. 5B), the state M01 may become a stable state under the condition of zero applied voltage.

If the state M01 rather than the state M00 is a stable state in the condition S4, detecting a change in the resistance value of the entire device between the state M00 and the state M01 involves using a positive voltage as one of the two applied voltages in FIG. 4. Here, a read voltage for use on the same side as the state M00 is denoted as vr1, and a read voltage for use on the same side as the state M01 is denoted as vr2. A resistance value r1 observed at the time of vr1 and a resistance value r2 observed at the time of vr2 are then related as r1<r2. As for resistance values observed for these two different applied voltages in the state M10 that is the other one of the stable states (i.e., memory states), the resistance value r1 at the time of vr1 and the resistance value r2 at the time of vr2 are not necessarily related as r1>r2, but r1<r2 may possibly occur. Namely, which one of the resistance values r1 and r2 compared with each other is greater than the other may not be reversed between the reading of the high-resistance state of the MTJ device 20 and the reading of the low-resistance state of the MTJ device 20. Accordingly, the magnetic coercive force of the second free layer 25 is preferably set such that the magnetization direction of the second free layer 25 always align in the second direction under the zero-applied-voltage condition, in order to ensure the reversal of the magnitude relationship between the resistance values compared with each other and thus to secure a sufficient voltage margin.

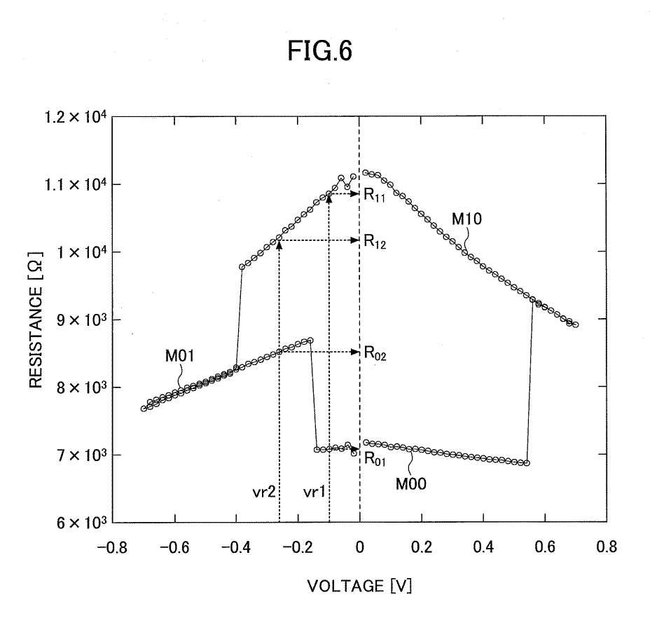

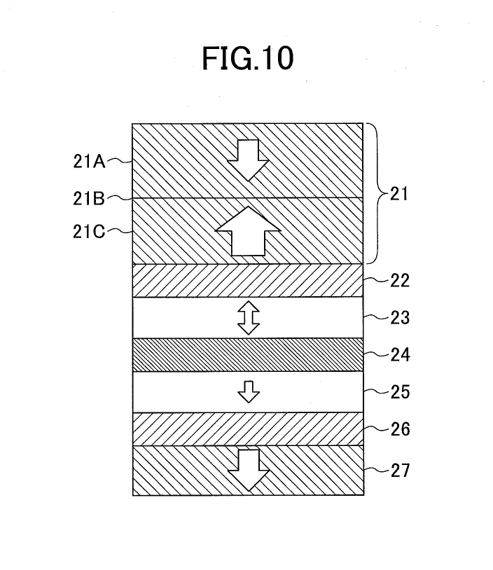

FIG. 6 is a drawing illustrating examples of the voltage-to-resistance characteristics and read voltages of a prototype MTJ device 20. A prototype of the MTJ device 20 having the characteristics described heretofore was made by using the structure that will be described later (see FIG. 10). In FIG. 6, the horizontal axis represents the voltage applied to the MTJ device 20, and the vertical axis represents the resistance value of the entire MTJ device 20.

The voltage-to-resistance characteristics of the prototype MTJ device 20 exhibited hysteresis characteristics as illustrated by open-circle plots in FIG. 6, which are similar to the exemplary hysteresis characteristics 30 illustrated in FIG. 4. When a voltage vr1 (approximately −0.1 V) as illustrated in FIG. 6 was applied to the MTJ device 20 having such voltage-to-resistance characteristics, a resistance value R₀₁ was observed in the state M00, and a resistance value R₁₁ was observed in the state M10. When a voltage vr2 (approximately −0.27 V) as illustrated in FIG. 6 was applied to the MTJ device 20, a resistance value R₀₂ was observed for the state M00, and a resistance value R₁₂ was observed in the state M10.

In the state M00 in which the first MTJ 101 of the MTJ device 20 is in the low-resistance state (i.e., in the parallel state), the two resistance values corresponding to the two read voltages vr1 and vr2 are related as R₀₁<R₀₂. In the state M10 in which the first MTJ 101 of the MTJ device 20 is in the high-resistance state (i.e., in the antiparallel state), the two resistance values corresponding to the two read voltages vr1 and vr2 are related as R₁₁>R₁₂. Namely, there are voltage points between which the combined resistance value of the first MTJ 101, the spacer 24, and the second MTJ 102 increases with an increase in the applied voltage in the case of the magnetization direction of the first free layer 23 being in the first direction. Further, this combined resistance value monotonously decreases with an increase in the applied voltage in the case of the magnetization direction of the first free layer 23 being in the second direction. In this manner, which one of the resistance values compared with each other is greater than the other is reversed in response to the data-written state of the MTJ device 20, thereby ensuring a sufficient margin to enable accurate data reading.

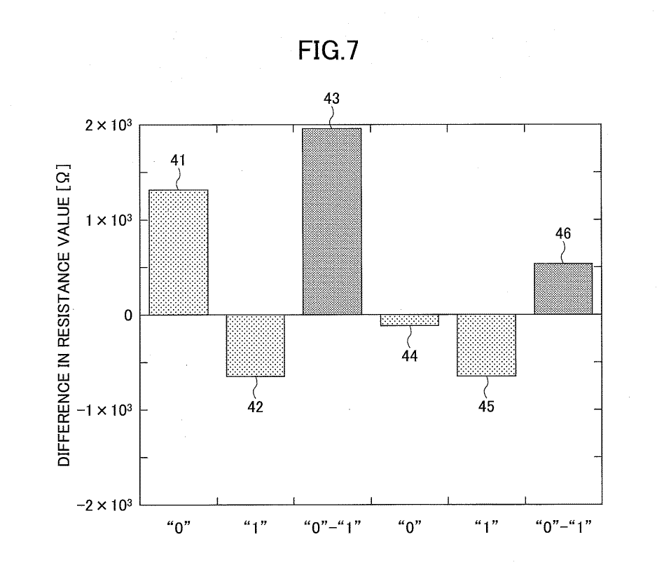

FIG. 7 is a drawing illustrating examples of a difference in the resistance value at the time of a read operation of an MTJ device. A bar 41 represents R₀₂-R₀₁ that is a difference between a resistance value R₀₁ observed at the time of applying the voltage vr1 (approximately −0.1 V) and a resistance value R₀₂ observed at the time of applying the voltage vr2 (approximately −0.27 V) to the MTJ device 20 in the state M00 illustrated in FIG. 6. A bar 42 represents R₁₂-R₁₁ that is a difference between a resistance value R₁₁ observed at the time of applying the voltage vr1 (approximately −0.1 V) and a resistance value R₁₂ observed at the time of applying the voltage vr2 (approximately −0.27 V) to the MTJ device 20 in the state M10 illustrated in FIG. 6. A bar 43 represents a difference between R₀₂-R₀₁ observed in the state M00 and R₁₂-R₁₁ observed in the state M10. The difference R₀₂-R₀₁ in the state M00 and the difference R₁₂-R₁₁ in the state M10 have signs opposite to each other, so that there is a large difference therebetween.

A bar 44 represents RC₀₂-RC₀₁ that is a difference between a resistance value RC₀₁ observed at the time of applying the voltage vr1 (approximately −0.1 V) and a resistance value RC₀₂ observed at the time of applying the voltage vr2 (approximately −0.27 V) to a comparative-purpose single MTJ in the low-resistance state. A bar 45 represents RC₁₂-RC₁₁ that is a difference between a resistance value RC₁₁ observed at the time of applying the voltage vr1 (approximately −0.1 V) and a resistance value RC₁₂ observed at the time of applying the voltage vr2 (approximately −0.27 V) to the comparative-purpose MTJ in the high-resistance state. A bar 46 represents a difference between RC₀₂-RC₀₁ observed in the low-resistance state and RC₁₂-RC₁₁ observed in the high-resistance state. As previously described, the resistance value of MTJ exhibits voltage dependency, and decreases as the applied voltage increases. The extent to which the resistance value decreases is large in the case of MTJ being in the high-resistance state, and is small in the case of MTJ being in the low-resistance state. However, the fact that the resistance value decreases with an increase in the voltage remains the same, so that the difference RC₀₂-RC₀₁ in the low-resistance state and the difference RC₁₂-RC₁₁ in the high-resistance state have the same sign, which results in a small difference therebetween. In this manner, a read data detection is made by using a small read margin in the case of a conventional MTJ, which may result in low reliability and an erroneous detection.

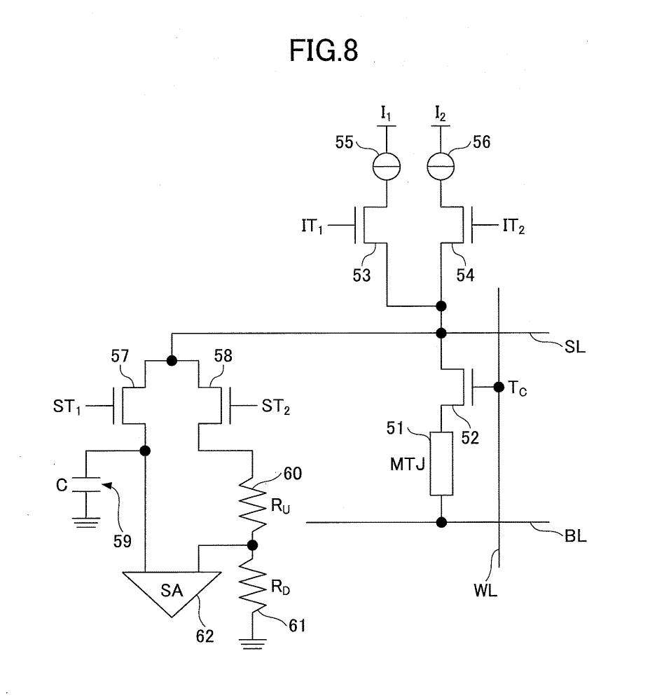

FIG. 8 is a drawing illustrating an example of the configuration of a read circuit for an MTJ device. The circuit illustrated in FIG. 8 includes an MTJ device 51, MOS transistors 52 through 54, current sources 55 and 56, MOS transistors 57 and 58, a capacitive element 59, resistive elements 60 and 61, and a sense amplifier 62. The circuit illustrated in FIG. 8 enables a nondestructive self-reference read operation. The MTJ device 51 may be the MTJ device 20 described heretofore.

At the time of data writing, a word line WL is activated to make the MOS transistor 52 conductive. Further, voltage is applied to the MTJ device 51 to cause an electric current to flow through a bit line BL and a source line SL in the direction varying in response to write data, thereby writing the data to the MTJ device 51.

At the time of data reading, the word line WL is activated to make the MOS transistor 52 conductive, and the bit line BL is coupled to the ground potential. Further, control signals IT₁ and ST₁ are activated to make the MOS transistors 53 and conductive. The conductive state of the MOS transistor 53 causes an electric current with a current amount I₁ originating from the current source 55 to flow through the MTJ device 51 into the ground potential of the bit line BL. With this arrangement, the voltage vr1 responsive to the current amount I₁ and the resistance value of the MTJ device 51 (i.e., the voltage responsive to the product of the current amount I₁ and the resistance value of the MTJ device 51) appears on the source line SL. As a result, the capacitive element 59 having a capacitance value C and coupled to the source line SL through the MOS transistor 57 is charged to the voltage value vr1. The control signals IT₁ and ST₁ are thereafter inactivated to make the MOS transistors 53 and 57 nonconductive.

Subsequently, control signals IT₂ and ST₂ are activated to make the MOS transistors 54 and 58 conductive. The conductive state of the MOS transistor 54 causes an electric current with a current amount I₂, which originates from the current source 56 and is greater than the current amount I₁ of the current source 55, to flow through the MTJ device 51 into the ground potential of the bit line BL. With this arrangement, the voltage vr2 responsive to the current amount I₂ and the resistance value of the MTJ device 51 (i.e., the voltage responsive to the product of the current amount I₂ and the resistance value of the MTJ device 51) appears on the source line SL. A potential divider circuit in which the resistive elements 60 and 61 with respective resistance values RU and RD are series-connected divides the voltage vr2 of the source line SL, and applies a divided voltage vd to one of the input nodes of the sense amplifier 62. The other input node of the sense amplifier 62 is coupled to the capacitive element 59. The sense amplifier 62 compares the divided voltage vd with the voltage vr1 held by the capacitive element 59 to produce an output responsive to the result of comparison. Specifically, the sense amplifier 62 outputs “0” in the case of vr1<vr2, and outputs “1” in the case of vr1>vr2.

In the manner described above, the sense amplifier 62 compares the values of an electric variable (e.g., voltages in the case of the example illustrated in FIG. 8) responsive to the resistance values of the MTJ device 51 between two different conditions regarding a voltage across the MTJ device 51. The sense amplifier 62 outputs a detection value indicative of data stored in the MTJ device 51 in response to the result of comparison of the values of the electric variable.

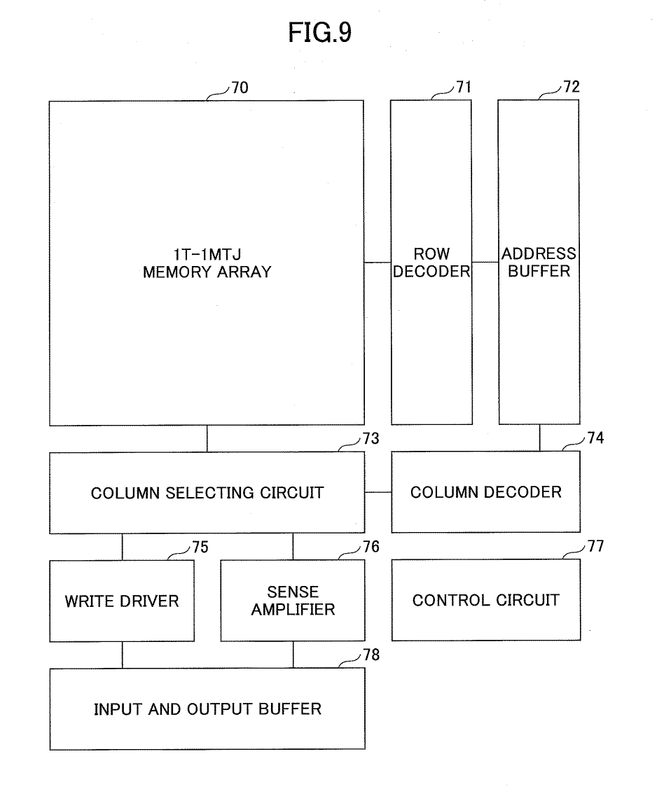

FIG. 9 is a drawing illustrating an example of the configuration of a semiconductor memory device utilizing the MTJ device 20. The semiconductor memory device illustrated in FIG. 9 includes a memory array 70, a row decoder 71, an address buffer 72, a column selecting circuit 73, a column decoder 74, a write driver 75, a sense amplifier 76, a control circuit 77, and an input and output buffer 78.

In FIG. 9, boundaries between functional or circuit blocks illustrated as boxes basically indicate functional boundaries, and may not correspond to separation in terms of physical positions, separation in terms of electrical signals, separation in terms of control logic, etc. Each functional or circuit block may be a hardware module that is physically separated from other blocks to some extent, or may indicate a function in a hardware module in which this and other blocks are physically combined together.

The control circuit 77 receives various control signals as command inputs from an external source. The control circuit 77 operates based on these control signals to control the operations of individual parts of the semiconductor memory device.

The memory array 70 includes a plurality memory cells arranged in rows and columns in a matrix in which each memory cell is implemented by use of the MTJ device 51 and the MOS transistor 52 illustrated in FIG. 8. Word lines, which are provided in one-to-one correspondence with the rows of memory cells, are coupled to the memory cells in the same or similar manner as the word line WL illustrated in FIG. 8. Bit lines and source lines, which are provided in one-to-one correspondence with the columns of memory cells, are coupled to the memory cells in the same or similar manner as in FIG. 8.

The input and output buffer 78, which receives data from an external source, supplies the data to the write driver 75. The address buffer 72 receives address signals from an external source for storage therein, and supplies the address signals to the row decoder 71 and the column decoder 74. The row decoder 71 decodes the address supplied from the address buffer 72, and selectively activates a word line in the memory array 70 in response to the result of decoding.

The column decoder 74 decodes the address supplied from the address buffer 72, and causes the column selecting circuit 73 to select a column indicated by the decoded address signals. With this arrangement, the column selecting circuit 73 selectively connects a source line and a bit line of the memory array 70 to a sense amplifier circuit in the sense amplifier 76.

The sense amplifier 76 performs a nondestructive self-reference read operation. Specifically, the MOS transistors 57 and 58, the capacitive element 59, the resistive elements 60 and 61, and the sense amplifier 62 may serve as the sense amplifier 76. The sense amplifier 76 compares the values of an electric variable (e.g., voltages or currents) read from a memory cell of the memory array 70 selected by the row decoder 71 and the column decoder 74 when the values of the electric variable are read under different conditions corresponding to different voltages applied to the MTJ device. In response to the result of comparison, the sense amplifier 76 determines whether the data stored in the selected memory cell is 0 or 1. The result of determination is supplied as read data to the input and output buffer 78.

At the time of a write operation, the write driver 75 sets a bit line BL and a source line SL to appropriate potentials in accordance with write data, with respect to a memory cell of the memory array 70 selected by the row decoder 71 and the column decoder 74. With this arrangement, data is written to the selected memory cell.

FIG. 10 is a drawing illustrating the configuration of a prototype MTJ device. The prototype MTJ device had a circular shape with a diameter of approximately 50 nm in a cross-section perpendicular to the thickness direction of each layer. The first pinned layer 21 included a first magnetic material layer 21A, an intermediate layer 21B, and a second magnetic material layer 21C. The magnetization direction of the first magnetic material layer 21A was downwards, and the magnetization direction of the second magnetic material layer 21C was upwards. The second magnetic material layer 21C had stronger magnetization than the first magnetic material layer 21A, so that the magnetization direction of the first pinned layer 21 as a whole is directed upwards. The first pinned layer 21 may be implemented as a single magnetic material layer. With too strong magnetization of the first pinned layer 21, however, the magnetization of the second pinned layer 27 ends up being relatively strong, which results in the undesirable consequence that the in-plane stray magnetic field is too strong in the first free layer 23. Too weak magnetization of the first pinned layer 21, on the other hand, leads to the problem that the magnetization thereof cannot be stably sustained. In consideration of this, two magnetic material layers having two different magnetization directions were bonded together to form the first pinned layer 21, thereby providing a desired magnetization strength in a stable manner. The first magnetic material layer 21A was CoPt with a thickness of 9 nm (which was constituted by 9 layers of Co/Pt each being 1 nm in thickness: the same will hereinafter apply). The intermediate layer 21B was Ru with a thickness of 1 nm. The second magnetic material layer 21C was constituted by CoPt with a thickness of 6 nm, Ta with a thickness of 0.4 nm, and CoFeB with a thickness of 1.7 nm in this order from the top in FIG. 10. As previously described, CoFeB was used to achieve a high MR ratio. Further, Ta was used to enable ferromagnetic bonding of CoPt and CoFeB having different crystal structures as a single magnetic material.

The tunnel insulating film 22 was MgO with a thickness of 0.9 nm. This MgO was made by forming a film of Mg to a thickness of 0.7 nm, oxidizing the Mg film for 60 seconds in the oxygen atmosphere, and then forming a film of Mg to a thickness of 0.2 nm for the purpose of preventing overoxidation of the interface. The first free layer 23 was CoFeB with a thickness of 0.8 nm.

The spacer 24 was constituted by Ta with a thickness of 1 nm, Ru with a thickness of 2 nm, and Ta with a thickness of 1 nm in this order from the top in FIG. 10. The use of Ta for the upper and lower interfaces of the spacer 24 is effective for the purpose of inducing perpendicular magnetic anisotropy in CoFeB. Ru was used for the purpose of adjusting the distance between the first free layer 23 and the second free layer 25. The film thickness of the spacer 24 may be set within a range of 1 nm to 10 nm to control properly the strength of a stray magnetic field from the first free layer 23 to the second free layer 25.

The second free layer 25 was CoFeB with a thickness of 1.7 nm. The tunnel insulating film 26 was MgO with a thickness of 0.9 nm. The second pinned layer 27 was constituted by CoFeB with a thickness of 0.85 nm, Ta with a thickness of 0.4 nm, and CoPt with a thickness of 6 nm in this order from the top in FIG. 10. As previously described, CoFeB was used to achieve a high MR ratio. Further, Ta was used to enable ferromagnetic bonding of CoPt and CoFeB having different crystal structures as a single magnetic material.

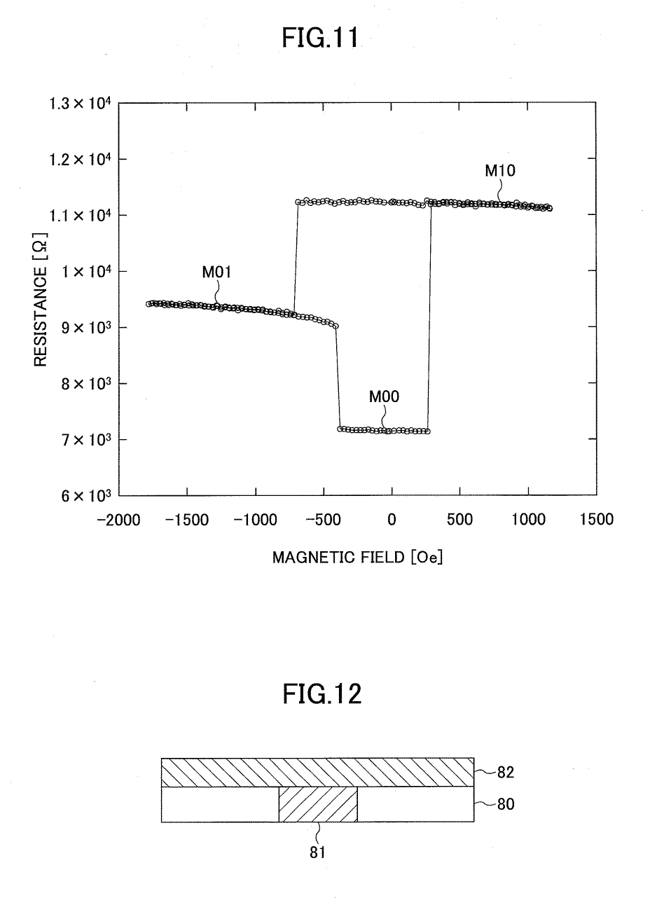

FIG. 11 is a drawing illustrating the magnetic-field-to-resistance characteristics of the prototype MTJ device. The prototype MTJ device had the voltage-to-resistance characteristics as illustrated in FIG. 6 as previously described, and exhibited hysteresis characteristics. The magnetic-field-to-resistance characteristics of the prototype MTJ device 20 also exhibited hysteresis characteristics as illustrated in FIG. 11. Application of negative voltage in FIG. 6 corresponds to application of a negative magnetic field in FIG. 11, and application of positive voltage in FIG. 6 corresponds to application of a positive magnetic field in FIG. 11. Differences between FIG. 6 and FIG. 11 arise from the fact that the state transitions exhibited by the same MTJ device are viewed from two different viewpoints based on two different physical quantities. What is illustrated is basically the same behavior of the same device.

Under the condition in which a strong negative magnetic field was applied, the MTJ device was placed in the state M01. As the applied magnetic field decreased, a transition to the state M00 occurred. The state M00 was maintained when the applied magnetic field was zero. A positive magnetic field was thereafter applied. As the magnitude of the magnetic field increased, a transition from the state M00 to the state M10 occurred. The state M10 was maintained when the magnitude of the positive magnetic field further increased.

When the applied magnetic field was thereafter decreased, the state M10 was maintained when the applied magnetic field was zero. A negative magnetic field was thereafter applied. As the magnitude of the magnetic field increased, a transition from the state M10 to the state M01 occurred. The state M01 was maintained when the magnitude of the negative magnetic field further increased.

FIG. 12 through FIG. 19 are drawings illustrating an example of the process steps of making the MTJ device. In FIG. 12, the initial state is such that a lower Cu wire 81 for connecting the lower electrode of the MTJ device to a selecting transistor is embedded in and exposed from an insulating film 80 made of such a material as SiO2. From this initial state, films of Ta(15)/Ru(25)/Ta(3) to become a lower electrode 82 are formed by sputtering where the listed order corresponds to ordinal positions from the top in FIG. 12, and the numeric values in the parentheses indicate the thicknesses in nanometers. Intermediate Ru of the lower electrode 82 has the function to lower the sheet resistance. The flatness of the surface improves compared to the case in which the same sheet resistance is obtained by use of only a Ta film. Ta on Ru serves as an etching stopper layer during dry etching of the MTJ.

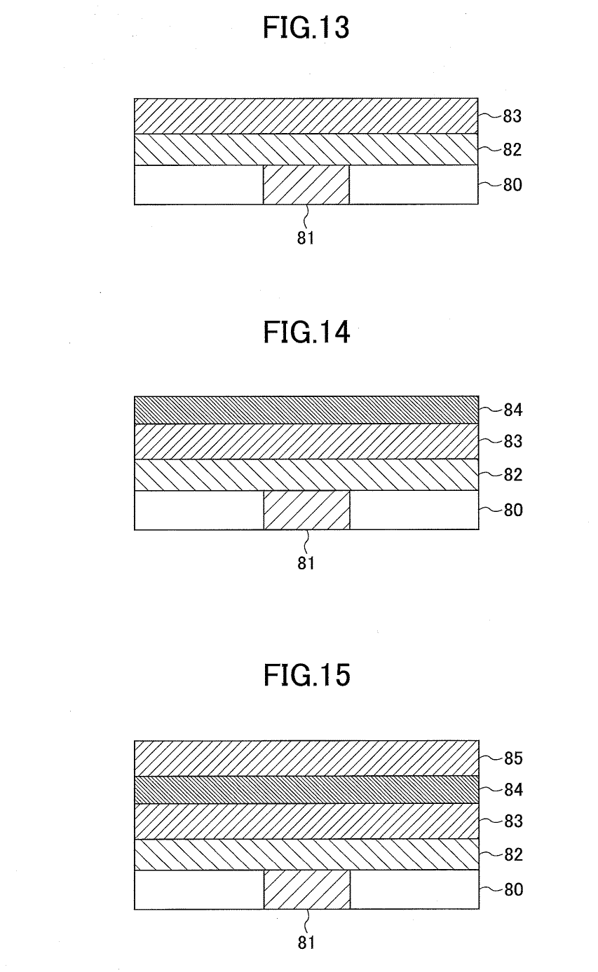

As illustrated in FIG. 13, an MTJ 83 (corresponding to the second MTJ 102 in FIG. 2) is formed by sputtering. The film composition of the MTJ 83 is CoFeB(1.7)/MgO(0.9)/CoFeB(0.85)/Ta(0.4)/CoPt(6)/Ru(8). CoPt(6) means that there are six laminated layers each of which is CoPt(1). CoFeB(0.85) and CoPt(6) are ferromagnetically coupled to each other via thin Ta(0.4). The composition ratio of CoFeB may be fixed to Co:Fe=1:3, and the composition of B may be adjusted between 20 and 25 (atomic %).

Thereafter, a spacer 84 is formed by sputtering as illustrated in FIG. 14. The film configuration of the spacer 84 is Ta(1)/Ru(2)/Ta(1). Use of Ta for the upper and lower interfaces of the spacer is effective for the purpose of inducing perpendicular magnetic anisotropy in CoFeB. Ru is used to adjust the distance between the two MTJs (i.e., the first MTJ 101 and the second MTJ 102 illustrated in FIG. 2).

As illustrated in FIG. 15, an MTJ 85 (corresponding to the first MTJ 101 in FIG. 2) is formed by sputtering. The MTJ 85 has a top-pinned structure, and has a film configuration of CoPt(9)/Ru(1)/CoPt(6)/Ta(0.4)/CoFeB(1.7)/MgO(0.9)/CoFeB(0.8). In the MTJ 85, natural oxidization may be used only for the formation of MgO. In natural oxidization, a film of Mg is formed to a thickness of 0.7 nm, and the Mg film is oxidized for 60 seconds in the oxygen atmosphere, followed by forming a film of Mg to a thickness of 0.2 nm for the purpose of preventing overoxidation of the interface. CoFeB(1.7) and CoPt(6) are ferromagnetically coupled to each other via thin Ta(0.4).

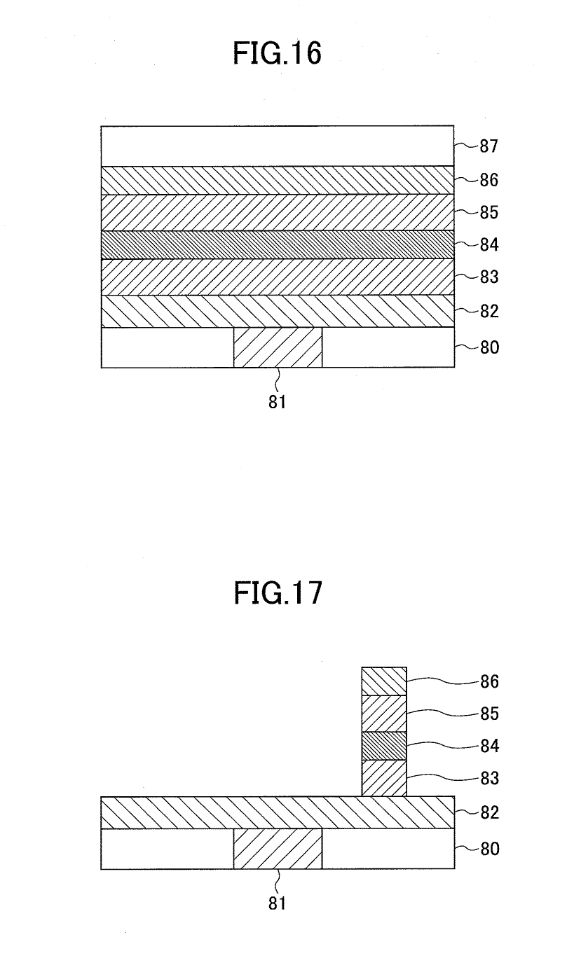

As illustrated in FIG. 16, thereafter, sputtering forms a film of Ru with a thickness of 7 nm serving as an etching stopper for an upper electrode 86 and a film of Ta with a thickness of 100 nm serving as the upper electrode 86. Further, CVD (chemical vapor deposition) forms a hard mask 87 made of SiO₂ with a thickness of 100 nm.

As illustrated in FIG. 17, an MTJ resist pattern is formed through exposure into a circular shape with a diameter of 50 nm by ArF immersion lithography and a three-layer resist process. Dry etching is then performed to etch the three-layer resist, the hard mask 87, the upper electrode 86, and the MTJ device 83 through 85. Etching is stopped at Ta of the lower electrode 82. Etching from the upper etching stopper to the pinned layer of the MTJ 83 may be performed by use of methanol as an etching gas, and is stopped at Ta serving as an etching stopper. By the time of completion of etching, SiO₂ serving as the hard mask has been removed by etching, and Ta of the upper electrode 86 is exposed.

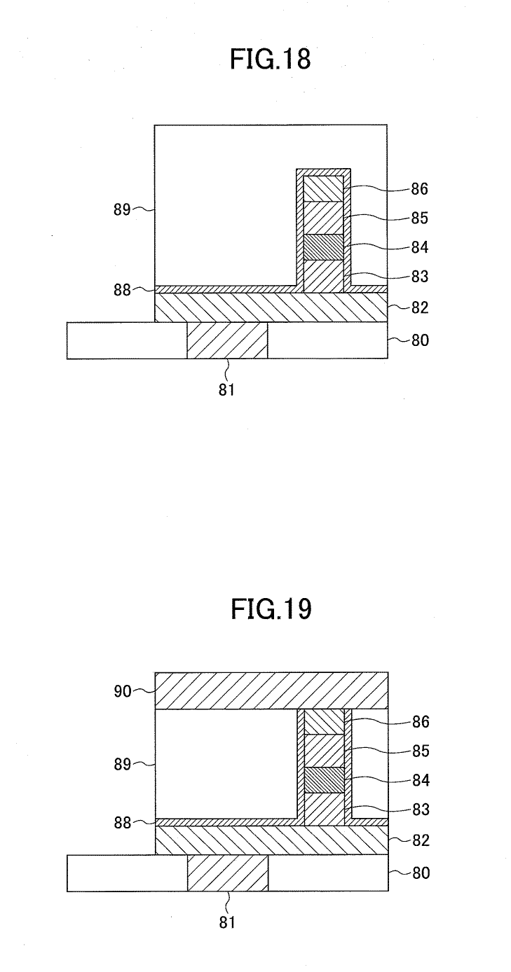

As illustrated in FIG. 18, thereafter, SiN serving as an interlayer insulating film 88 is formed to a thickness of 30 nm, followed by forming and planarizing SiO₂ serving as a thick interlayer insulating film 89 to a thickness of 100 nm. In order to separate the MTJs electrically from each other (only one MTJ is illustrated in this example), a resist pattern for the lower electrode 82 is formed through exposure such as to cover the MTJs and Cu plugs by ArF immersion lithography and a three-layer resist process. Dry etching is then performed to etch the three-layer resist, SiO₂(89), SiN(88), and the lower electrode 82, and is stopped at SiO₂(80) situated beneath the lower electrode 82. Processes that are to be subsequently performed are substantially the same as or similar to a copper dual damascene process. SiO2 serving as an interlayer insulating film is formed to a thickness of 300 nm, followed by CMP (chemical mechanical polishing) for planarization. Further, vias are formed at their respective positions, and the top of the MTJ is etched to expose the upper electrode 86, followed by embedding copper into the exposed portion and then using CMP for planarization, thereby forming an upper wire 90 as illustrated in FIG. 19. After this, copper wires, aluminum pads, and the like may be formed at further upper layers.

The materials, film thicknesses, conditions, and the like used in the above-noted embodiments are examples only, and are not intended to be limiting. For example, the fact that interface perpendicular magnetic anisotropy is induced at the MgO/CoFeB interface for various compositions of CoFeB is known in the art, so that an applicable composition is not limited to a particular composition. The method of forming MgO serving as a tunnel insulating film may be either direct sputtering using an MgO target or a method of oxidizing metal Mg after sputter-based film formation. In place of CoPt used to assist CoFeB in the pinned layer, an alternative ferromagnetic material having perpendicular magnetization such as Co/Pd or Co/Ni may be used, and, further alternatively, a structure obtained by combining these ferromagnetic materials may be used. Although Ta/Ru/Ta was used as a spacer material, any material may be used as long as such a material allows the free layers of the two MTJs to sustain perpendicular magnetic anisotropy. The film thickness of the spacer may be such as to create magnetic-field interference between the two free layers, and may preferably be from 1 nm to 10 nm. In the present embodiment, the structure is such that the lower MTJ is the second MTJ 102, and the upper MTJ is the first MTJ 101. A structure obtained by flipping this arrangement upside down may alternatively be used.

In the structure illustrated in FIG. 10, only the first pinned layer 21 has a multiple-layer structure, and the second pinned layer 27 has a single layer structure. Not only the first pinned layer 21 but also the second pinned layer 27 may be implemented as having a multiple-layer configuration.

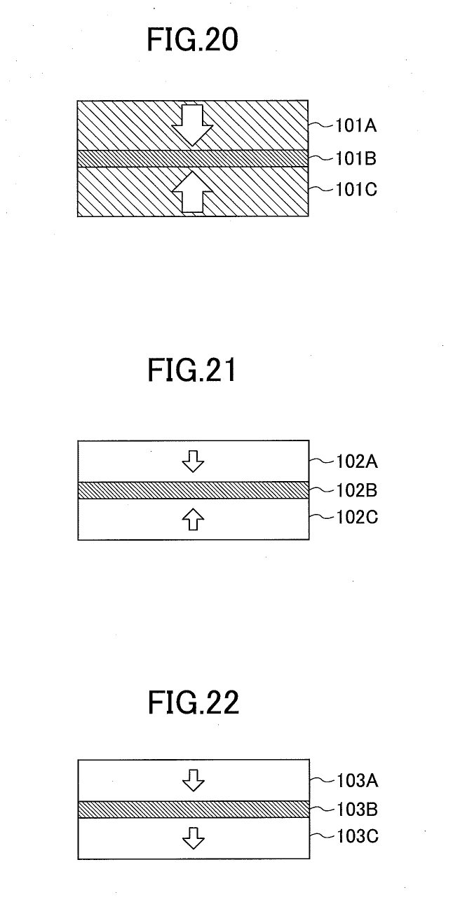

FIG. 20 is a drawing illustrating an example of the configuration of a pinned layer. The pinned layer illustrated in FIG. 20 includes a first magnetic material layer 101A, an intermediate layer 101B, and a second magnetic material layer 101C. The magnetization direction of the first magnetic material layer 101A is downwards, and the magnetization direction of the second magnetic material layer 101C is upwards. The first magnetic material layer 101A and the second magnetic material layer 101C have different magnetization strengths, and the pinned layer as a whole may achieve a desired magnetization direction. In the case of a pinned layer being formed as a single magnetic material layer, too strong magnetization is not preferable because an in-plane stray magnetic field becomes too strong. Too weak magnetization, on the other hand, gives rise to a problem in that the magnetization cannot be sustained in a stable manner. In consideration of this, two magnetic material layers having two different magnetization directions are antiferromagnetically coupled through Ru to form a pinned layer, thereby providing a desired magnetization strength in a stable manner.

FIG. 21 is a drawing illustrating an example of the configuration of a free layer. Similarly to the configuration illustrated in FIG. 20, the free layer may also be formed as having a multiple-layer configuration. The free layer illustrated in FIG. 21 includes a first magnetic material layer 102A, an intermediate layer 102B, and a second magnetic material layer 102C. Two magnetic material layers are antiferromagnetically coupled through Ru to form a free layer, thereby providing a desired magnetization strength in a stable manner.

FIG. 22 is a drawing illustrating another example of the configuration of a free layer. The free layer illustrated in FIG. 22 includes a first magnetic material layer 103A, an intermediate layer 103B, and a second magnetic material layer 103C. The two magnetic material layers are ferromagnetically coupled through Ru to form a free layer, thereby providing a desired magnetization strength in a stable manner.

According to at least one embodiment, an MTJ device and a semiconductor memory device are provided that realize a sufficient operation margin in a data read operation utilizing the voltage dependency of an MTJ resistance value.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A magnetic tunnel junction device, comprising:
a first magnetic tunnel junction including a first free layer and a first pinned layer, the first pinned layer having magnetization thereof aligned in a first direction; and
a second magnetic tunnel junction including a second free layer and a second pinned layer, the second free layer being magnetically coupled to the first free layer via a spacer, and the second pinned layer having magnetization thereof aligned in a second direction opposite the first direction,
wherein a magnetization direction of the first free layer is configured to be retained in a nonvolatile manner upon being selectively set to either the first direction or the second direction, and a readiness of the magnetization of the second free layer to be reversed varies depending on the magnetization direction of the first free layer.

2. The magnetic tunnel junction device as claimed in claim 1, wherein a value of an applied voltage or an applied magnetic field to reverse the magnetization of the second free layer varies depending on the magnetization direction of the first free layer.

3. The magnetic tunnel junction device as claimed in claim 1, wherein a magnetic coercive force of the second free layer is set such that a magnetization direction of the second free layer always aligns in the second direction regardless of the magnetization direction of the first free layer when an applied voltage or an applied magnetic field is zero.

4. The magnetic tunnel junction device as claimed in claim 1, wherein in a case of the magnetization direction of the first free layer being the first direction, a magnetization direction of the second free layer is the second direction when a first voltage is applied, and is the first direction when a second voltage greater than the first voltage is applied, and wherein in a case of the magnetization direction of the first free layer being the second direction, the magnetization direction of the second free layer is the second direction when the first voltage is applied, and is the second direction when the second voltage is applied.

5. The magnetic tunnel junction device as claimed in claim 1, wherein a total resistance value of the first magnetic tunnel junction, the spacer, and the second magnetic tunnel junction increases when an applied voltage increases from a certain voltage in a case of the magnetization direction of the first free layer being the first direction, and the total resistance value monotonously decreases when the applied voltage increases in a case of the magnetization direction of the first free layer being the second direction.

6. The magnetic tunnel junction device as claimed in claim 1, wherein a change in a resistance value of the first magnetic tunnel junction caused by a reversal of the magnetization direction of the first free layer is smaller than a change in a resistance value of the second magnetic tunnel junction caused by a reversal of a magnetization direction of the second free layer.

7. The magnetic tunnel junction device as claimed in claim 1, wherein a film thickness of the spacer is greater than or equal to 1 nm and smaller than or equal to 10 nm.

8. A semiconductor memory device, comprising:
a magnetic tunnel junction device; and
a circuit configured to compare values of an electric variable responsive to resistance values of the magnetic tunnel junction device between two different conditions regarding a voltage across the magnetic tunnel junction device, and configured to output a detection value of data stored in the magnetic tunnel junction device in response to a result of comparison of the values of the electric variable,
wherein the magnetic tunnel junction device includes:
a first magnetic tunnel junction including a first free layer and a first pinned layer, the first pinned layer having magnetization thereof aligned in a first direction; and
a second magnetic tunnel junction including a second free layer and a second pinned layer, the second free layer being magnetically coupled to the first free layer via a spacer, and the second pinned layer having magnetization thereof aligned in a second direction opposite the first direction,
wherein a magnetization direction of the first free layer is configured to be retained in a nonvolatile manner upon being selectively set to either the first direction or the second direction, and a readiness of the magnetization of the second free layer to be reversed varies depending on the magnetization direction of the first free layer.

9. The semiconductor memory device as claimed in claim 8, wherein a value of a voltage applied to the magnetic tunnel junction device to reverse the magnetization of the second free layer varies depending on the magnetization direction of the first free layer.

10. The semiconductor memory device as claimed in claim 8, wherein a magnetic coercive force of the second free layer is set such that a magnetization direction of the second free layer always aligns in the second direction due to a magnetic field from the second pinned layer, regardless of the magnetization direction of the first free layer when a voltage applied to the magnetic tunnel junction device is zero.

11. The semiconductor memory device as claimed in claim 8, wherein in a case of the magnetization direction of the first free layer being the first direction, a magnetization direction of the second free layer is the second direction when a first voltage is applied to the magnetic tunnel junction device, and is the first direction when a second voltage greater than the first voltage is applied to the magnetic tunnel junction device, and wherein in a case of the magnetization direction of the first free layer being the second direction, the magnetization direction of the second free layer is the second direction when the first voltage is applied to the magnetic tunnel junction device, and is the second direction when the second voltage is applied to the magnetic tunnel junction device.
